(19) United States
(12) Patent Application Publication
(10) Pub. No.: US 2007/0200151 A1
(43) Pub. Date: Aug. 30, 2007

(54) Semiconductor device and method of fabricating the same

(75) Inventor: Hideaki Fujiwara, Hashima-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/709,752

(22) Filed: Feb. 23, 2007

(30) Foreign Application Priority Data
Feb. 24, 2006 (JP) JP2006-047710

(51) Int. Cl. H01L 29/76

(52) U.S. Cl. 257/288

(57) ABSTRACT

A semiconductor device capable of suppressing reduction of the electric characteristics and fluctuation of the threshold voltage resulting from ion implantation is obtained. This semiconductor device comprises a pair of source/drain regions formed on the main surface of a semiconductor region to hold a channel region therebetween and a gate electrode formed on the channel region through a gate insulating film, and the gate electrode includes a first metal-containing layer, a second metal-containing layer formed on the first metal-containing layer and an intermediate layer formed between the first metal-containing layer and the second metal-containing layer.

### BACKGROUND OF THE INVENTION

1. Field of the Invention

The present invention relates to a semiconductor device and a method of fabricating the same, and more particularly, it relates to a semiconductor device comprising a gate electrode and a method of fabricating the same.

2. Description of the Background Art

A MOS transistor is generally known as a semiconductor device comprising a gate electrode. In such a semiconductor device, a gate electrode consisting of a polysilicon layer is formed on a silicon substrate (channel region) through a gate insulating film. In a step of fabricating the conventional MOS transistor, an impurity is ion-implanted into the gate electrode (polysilicon layer) from above the gate electrode, thereby forming source/drain regions and imparting conductivity to the gate electrode.

In the conventional MOS transistor, however, impurity ions may punch through the gate insulating film located under the gate electrode to reach the silicon substrate (channel region) unless ion implantation is performed with sufficiently low energy in the ion implantation step for forming the source/drain regions and imparting conductivity to the gate electrode. Therefore, the gate insulating film is damaged to generate a leakage current, while an interfacial level is formed on the interface between the gate insulating film and the silicon substrate to disadvantageously reduce mobility of electrons and holes. Consequently, the electric characteristics of the MOS transistor (semiconductor device) are disadvantageously reduced. Further, the threshold voltage of the MOS transistor problematically fluctuates to an unintended value due to change in the impurity concentration of the channel region.

### SUMMARY OF THE INVENTION

The present invention has been proposed in order to solve the aforementioned problems, and an object of the present invention is to provide a semiconductor device capable of suppressing reduction of the electric characteristics and fluctuation of the threshold voltage resulting from ion implantation.

Another object of the present invention is to provide a method of fabricating a semiconductor device capable of suppressing reduction of the electric characteristics and fluctuation of the threshold voltage resulting from ion implantation.

A semiconductor device according to a first aspect of the present invention comprises a pair of source/drain regions formed on the main surface of a semiconductor region to hold a channel region therebetween and a gate electrode formed on the channel region through a gate insulating film. The gate electrode includes a first metal-containing layer, a second metal-containing layer formed on the first metal-containing layer and an intermediate layer formed between the first metal-containing layer and the second metal-containing layer.

A method of fabricating a semiconductor device according to a second aspect of the present invention comprises steps of forming a gate electrode by successively forming a first metal-containing layer, an intermediate layer and a second metal-containing layer on the main surface of a semiconductor region through a gate insulating film and ion-implanting an impurity from above the gate electrode.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of an n-channel MOS transistor according to an embodiment of the present invention; and

FIGS. 2 to 8 are sectional views for illustrating a process of fabricating the n-channel MOS transistor according to the embodiment of the present invention.

### DESCRIPTION OF THE PREFERRED EMBODIMENTS

An embodiment of the present invention is now described with reference to the drawings.

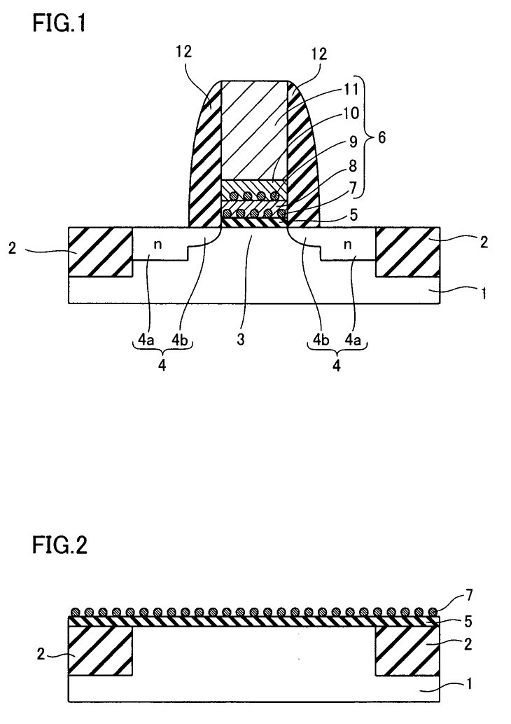

First, the structure of an n-channel MOS transistor according to this embodiment is described with reference to FIG. 1.

According to this embodiment, element isolation films 2 of SiO₂ are formed on prescribed regions of a p-type silicon substrate 1, as shown in FIG. 1. These element isolation films 2 are provided for isolating the n-channel MOS transistor according to this embodiment from semiconductor elements (not shown) other than this n-channel MOS transistor. A pair of n-type source/drain regions 4 are formed on the silicon substrate 1 to hold a p-type channel region 3 therebetween. Each source/drain region 4 includes an n-type high-concentration impurity region 4a and an n-type low-concentration impurity region 4b having a lower impurity concentration than the n-type high-concentration impurity region 4a. The silicon substrate 1 is an example of the “semiconductor region” in the present invention.

A gate electrode 6 is formed on the channel region 3 through a gate insulating film 5 consisting of an SiO₂ film having a thickness of not more than about 6 nm. The channel region 3 and the source/drain regions 4, the gate insulating film 5 and the gate electrode 6 constitute the n-channel MOS transistor.

According to this embodiment, the gate electrode 6 includes metal-containing layers 7 and 9 containing TaN and n⁺-type polysilicon layers 8, 10 and 11. The gate electrode 6 of the n-channel MOS transistor according to this embodiment is so formed that the metal-containing layers 7 and 9 are arranged in the vicinity of the interface between the gate electrode 6 and the gate insulating film 5. The metal-containing layers 7 and 9 are examples of the “first metal-containing layer” and the “second metal-containing layer” in the present invention respectively, and the polysilicon layer 8 is an example of the “intermediate layer” in the present invention. The polysilicon layers 10 and 11 are examples of the “semiconductor layer” in the present invention.

More specifically, the metal-containing layer 7 of the gate electrode 6 of the n-channel MOS transistor according to this embodiment is provided on the gate insulating film 5 with a small average thickness of not more than about 2.5 nm (in film formation) in the form of dots to partially cover the surface of the gate insulating film 5. The polysilicon layer 8 is formed on the metal-containing layer 7 with a thickness of about 10 nm, to come into contact with the surface of the gate insulating film 5 through regions located between adjacent ones of the dots forming the metal-containing layer 7.

The metal-containing layer 9 is provided on the polysilicon layer 8 with a small average thickness of not more than about 2.5 nm (in film formation) in the form of dots to partially cover the surface of the polysilicon layer 8. According to this embodiment, regions (on which the dots are located) formed with the lower metal-containing layer 7 and regions (on which the dots are located) formed with the upper metal-containing layer 9 deviate from each other in a direction parallel to the surface of the gate insulating film 5 in plan view. The metal-containing layers 7 and 9 are provided on the surfaces of the gate insulating film 5 and the polysilicon layer 8 to disperse substantially over the whole areas thereof respectively. The polysilicon layer 10 is formed on the metal-containing layer 9 with a thickness of about 10 nm, to come into contact with the surface of the polysilicon layer 8 through regions located between adjacent ones of the dots forming the metal-containing layer 9. In other words, the metal-containing layer 9 is arranged in the vicinity of the interface between the polysilicon layers 8 and 10. The polysilicon layer 11 is formed on the polysilicon layer 10 with a thickness of about 100 nm.

Side wall films 12 of SiO₂ are formed on the n-type low-concentration impurity regions 4b of the source/drain regions 4, to cover the side surfaces of the gate insulating film 5 and the gate electrode 6.

According to this embodiment, as hereinabove described, the gate electrode 6 formed on the channel region 3 through the gate insulating film 5 includes the metal-containing layer 7 and the other metal-containing layer 9 formed on this metal-containing layer 7, so that the upper metal-containing layer 9 can inhibit impurity ions from progressing toward the gate insulating film 5 when an impurity is ion-implanted into the gate electrode 6 from above the gate electrode 6 in order to form the source/drain regions 4 and impart conductivity to the polysilicon layers 8, 10 and 11 of the gate electrode 6 in a step of fabricating the n-channel MOS transistor. If the impurity ions pass through the metal-containing layer 9, the metal-containing layer 7 provided under the same can inhibit these impurity ions from progressing toward the gate insulating film 5. Therefore, the quantity of impurity ions reaching the gate insulating film 5 can be reduced, whereby the impurity ions can be inhibited from punching through the gate insulating film 5. Thus, damage of the gate insulating film 5 can be suppressed, whereby a leakage current can be inhibited from flowing through the gate insulating film 5. Further, the interface between the gate insulating film 5 and the silicon substrate 1 can be inhibited from formation of an interfacial level, whereby reduction of electron mobility can be suppressed in the channel region 3. Consequently, the n-channel MOS transistor can be inhibited from reduction of the electric characteristics resulting from the ion implantation. In addition, the impurity ions punching through the gate insulating film 5 can be inhibited from reaching the silicon substrate 1, whereby the threshold voltage of the n-channel MOS transistor can be inhibited from fluctuating to an unintended value due to change of the impurity concentration of the channel region 3.

According to this embodiment, as hereinabove described, the lower metal-containing layer 7 is provided in the form of dots to partially cover the surface of the gate insulating film 5, whereby stress acting between the metal-containing layer 7 and the gate insulating film 5 and the silicon substrate 1 can be reduced as compared with a case of forming the metal-containing layer 7 to cover the overall surface of the gate insulating film 5. Thus, the channel region 3 can be inhibited from reduction of the electron mobility resulting from large stress acting between the metal-containing layer 7 and the gate insulating film 5 and the silicon substrate 1.

According to this embodiment, as hereinabove described, the upper metal-containing layer 9 is provided in the form of dots to partially cover the surface of the polysilicon layer 8, whereby the impurity ions can be easily diffused into the polysilicon layer 8 through the regions located between adjacent ones of the dots forming the metal-containing layer 9 when the impurity is ion-implanted into the polysilicon layer 8 from above the gate electrode 6 in order to impart conductivity to the gate electrode 6 (polysilicon layer 8) in the step of fabricating the n-channel MOS transistor. In this case, the regions (on which the dots are located) formed with the lower metal-containing layer 7 and the regions (on which the dots are located) formed with the upper metal-containing layer 9 deviate from each other in the direction parallel to the surface of the gate insulating film 5 in plan view, so that the lower metal-containing layer 7 formed on the regions deviating from those formed with the upper metal-containing layer 9 in the direction parallel to the surface of the gate insulating film 5 can easily inhibit the impurity ions from progressing toward the gate insulating film 5 when the impurity ions pass through the regions located between the dots forming the upper metal-containing layer 9.

According to this embodiment, as hereinabove described, the metal-containing layers 7 and 9 are arranged in the vicinity of the interface between the gate electrode 6 and the gate insulating film 5 so that the metal density of the gate electrode 6 can be increased in the vicinity of the interface between the same and the gate insulating film 5 as compared with a case of arranging only a polysilicon layer in the vicinity of the interface between the gate electrode 6 and the gate insulating film 5, whereby the gate electrode 6 can be inhibited from depletion.

A process of fabricating the n-channel MOS transistor according to this embodiment is now described with reference to FIGS. 1 to 8.

First, regions of the p-type silicon substrate 1 to be formed with the element isolation films 2 are removed by photolithography and etching, as shown in FIG. 2. Thereafter the element isolation films 2 of SiO₂ are embedded in the aforementioned removed regions of the silicon substrate 1 by CVD (chemical vapor deposition).

Then, the gate insulating film 5 of SiO₂ having the thickness of not more than about 6 nm is formed on the overall surface by CVD. Thereafter the metal-containing layer 7 containing TaN is formed on the gate insulating film 5 by CVD with the small average thickness of not more than about 2.5 nm (in film formation). At this time, the metal-containing layer 7 is deposited in a nonlayered manner due to the small average thickness (not more than about 2.5 nm) thereof. Therefore, the metal-containing layer 7 is conceivably partially formed on the gate insulating film 5.

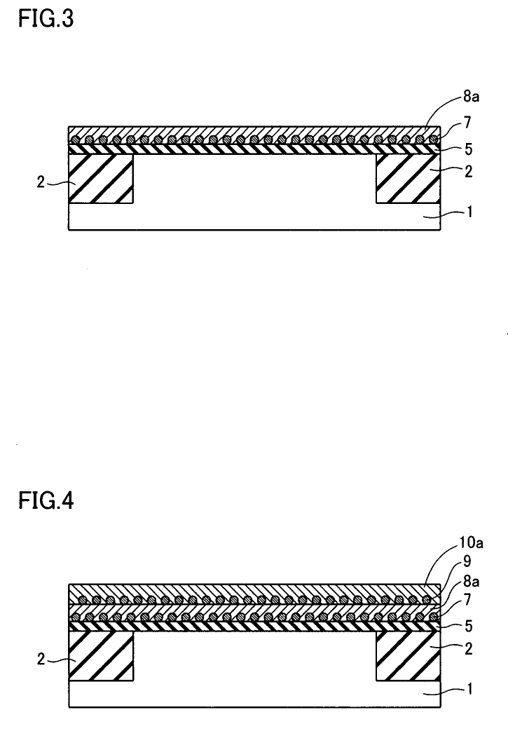

As shown in FIG. 3, an amorphous silicon layer 8a having a thickness of about 10 nm is formed on the metal-containing layer 7 by CVD. The metal-containing layer 7 partially formed on the gate insulating film 5 conceivably flocculates in the form of dots due to heat supplied in the CVD step for forming the aforementioned amorphous silicon layer 8a, a heat treatment step for electrically activating the impurity as described below and the remaining steps. Therefore, the amorphous silicon layer 8a located on the metal-containing layer 7 is so formed as to come into contact with the surface of the gate insulating film 5 through the regions located between adjacent ones of the dots forming the metal-containing layer 7.

According to this embodiment, the metal-containing layer 9 containing TaN is formed on the amorphous silicon layer 8a by CVD with the small average thickness of not more than about 2.5 nm (in film formation), as shown in FIG. 4. At this time, the metal-containing layer 9 is conceivably partially formed on the amorphous silicon layer 8a due to the small average thickness (not more than about 2.5 nm) thereof, similarly to the aforementioned metal-containing layer 7. Then, another amorphous silicon layer 10a having a thickness of about 10 nm is formed on the metal-containing layer 9 by CVD. At this time, the metal-containing layer 9 conceivably flocculates in the form of dots similarly to the metal-containing layer 7 flocculating in formation of the aforementioned amorphous silicon layer 8a, whereby the amorphous silicon layer 10a located on the metal-containing layer 9 is so formed as to come into contact with the surface of the amorphous silicon layer 8a through the regions located between adjacent ones of the dots forming the metal-containing layer 9. Further, the regions (on which the dots are located) formed with the upper metal-containing layer 9 conceivably deviate from the regions (on which the dots are located) formed with the lower metal-containing layer 7 in the direction parallel to the surface of the gate insulating film 5 in plan view. In addition, an interface observable with a TEM (transmission electron microscope) is formed between the amorphous silicon layers 8a and 10a.

As shown in FIG. 5, still another amorphous silicon layer 11a having a thickness of about 100 nm is formed on the amorphous silicon layer 10a by CVD. An interface observable with a TEM is formed between the amorphous silicon layers 10a and 11a. Thereafter a resist film 13 is formed on a prescribed region of the amorphous silicon layer 11a by photolithography.

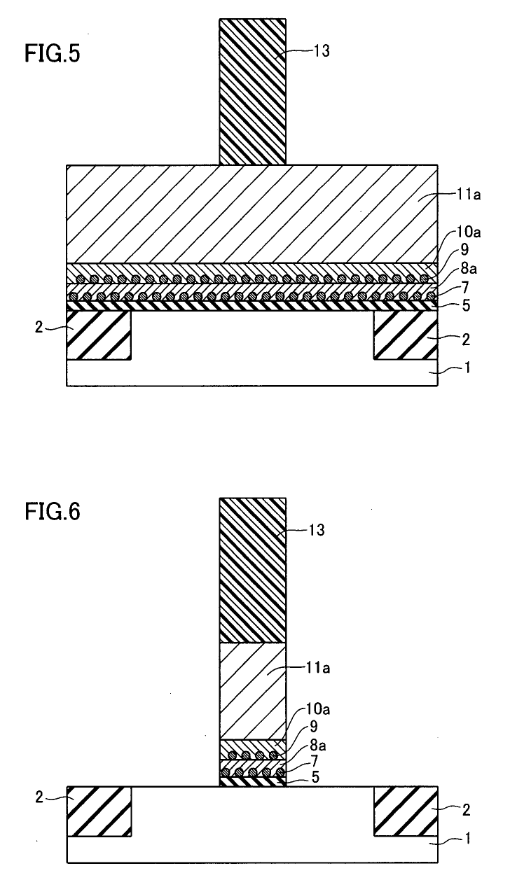

As shown in FIG. 6, the resist film 13 is employed as a mask for etching the amorphous silicon layers 11a and 10a, the metal-containing layer 9, the amorphous silicon layer 8a, the metal-containing layer 7 and the gate insulating film 5 by RIE (reactive ion etching). Thereafter the resist film 13 is removed.

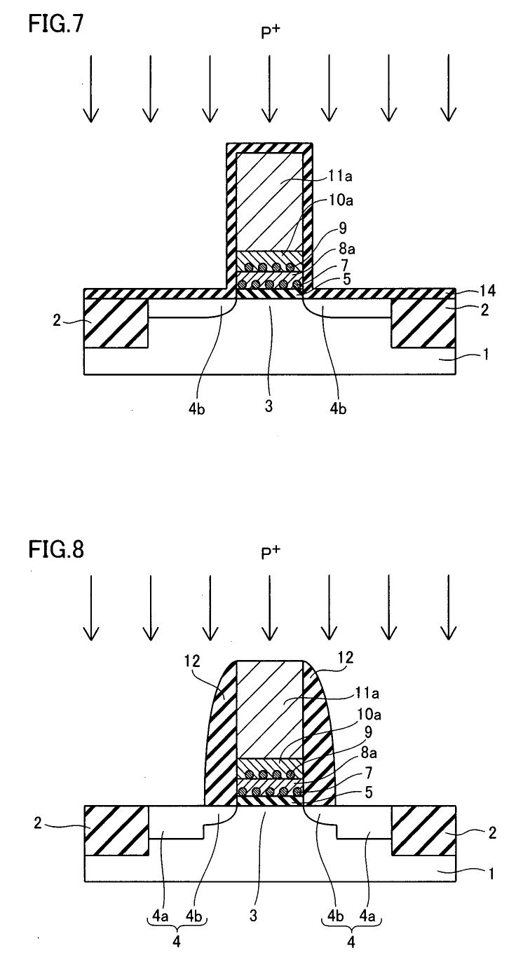

As shown in FIG. 7, an SiO₂ film 14 having a thickness of about 10 nm is formed by CVD to cover the overall surface. This SiO₂ film 14 has a function of suppressing damage in the vicinity of edges of the gate insulating film 5 in an ion implantation step described later. Thereafter phosphorus (P) employed as an n-type impurity is ion-implanted from above the upper surface of the silicon substrate 1 with a low concentration. Thus, the pair of n-type low-concentration impurity regions 4b are formed on the silicon substrate 1 to hold the p-type channel region 3 (located under the gate insulating film 5). Further, phosphorus ions are introduced into the amorphous silicon layers 11a, 10a and 8a.

According to this embodiment, the metal-containing layer 9 is provided in the form of dots to partially cover the surface of the polysilicon layer 8, whereby the phosphorus ions can be introduced into the amorphous silicon layer 8a through the regions located between adjacent ones of the dots forming the metal-containing layer 9. Further, the regions (on which the dots are located) formed with the lower and upper metal-containing layers 7 and 9 deviate from each other in the direction parallel to the surface of the gate insulating film 5 in plan view, whereby the lower metal-containing layer 7 can inhibit phosphorus ions, progressing toward the gate insulating film 5 and passing through the regions located between adjacent ones of the dots forming the upper metal-containing layer 9, from progressing toward the gate insulating film 5. Thus, the quantity of phosphorus ions reaching the gate insulating film 5 can be reduced, whereby the phosphorus ions can be inhibited from passing through the gate insulating film 5.

As shown in FIG. 8, another SiO₂ film (not shown) is formed by CVD to cover the overall surface and etched back, thereby forming the side wall films 12 of SiO₂ to cover the side surfaces of the amorphous silicon layers 11a and 10a, the metal-containing layer 9, the amorphous silicon layer 8a, the metal-containing layer 7 and the gate insulating film 5. Thereafter phosphorus (P) employed as the n-type impurity is ion-implanted from above the upper surface of the silicon substrate 1 with a high concentration. Thus, the pair of source/drain regions 4 including the n-type high-concentration impurity regions 4a and the n-type low-concentration impurity regions 4b respectively are formed on the silicon substrate 1 to hold the p-type channel region 3 therebetween. Further, phosphorus ions are introduced into the amorphous silicon layers 11a, 10a and 8a. At this time, the quantity of phosphorus ions reaching the gate insulating film 5 can be reduced similarly to the ion implantation step shown in FIG. 7, whereby the phosphorus ions can be inhibited from punching through the gate insulating film 5.

Then, heat treatment (at about 950° C. for about 20 seconds) is performed by RTA (rapid thermal annealing), thereby electrically activating the impurity introduced into the source/drain regions 4 and the amorphous silicon layers 8a, 10a and 11a. The amorphous silicon layers 8a, 10a and 11a are crystallized due to this heat treatment. Thus, the gate electrode 6 including the metal-containing layers 7 and 9 containing TaN and the n⁺-type polysilicon layers 8, 10 and 11 is formed as shown in FIG. 1. The n-channel MOS transistor according to this embodiment is formed in this manner.

Although the present invention has been described and illustrated in detail, it is clearly understood that the same is by way of illustration and example only and is not to be taken by way of limitation, the spirit and scope of the present invention being limited only by the terms of the appended claims.

For example, while the present invention is applied to the n-channel MOS transistor in the aforementioned embodiment, the present invention is not restricted to this but is also applicable to a p-channel MOS transistor or a CMOS device including an n-channel MOS transistor and a p-channel MOS transistor. When the present invention is applied to a CMOS device, a plurality of metal-containing layers may be provided only on a gate electrode of either the n-channel MOS transistor or the p-channel MOS transistor, or on the gate electrode of each of the n- and p-channel MOS transistors.

While the gate electrode includes two metal-containing layers in the aforementioned embodiment, the present invention is not restricted to this but the gate electrode may alternatively be provided with at least three metal-containing layers.

While the metal-containing layers are provided in the vicinity of the interface between the gate electrode and the gate insulating film in the aforementioned embodiment, the present invention is not restricted to this but the metal-containing layers may alternatively be provided on a region other than that close to the interface between the gate electrode and the gate insulating film.

While the metal-containing layers are provided in the form of dots to partially cover the surface of the gate insulating film in the aforementioned embodiment, the present invention is not restricted to this but the metal-containing layers may alternatively be provided in a shape other than the dotted shape to partially cover the surface of the gate insulating film.

While the metal-containing layers in the form of dots are so provided as to partially cover the surface of the gate insulating film in the aforementioned embodiment, the present invention is not restricted to this but metal-rich silicide grains having a metal concentration of at least about 50% or silicon-rich silicide and silicon grains may be distributed in metal-containing layers so formed as to cover the overall surface of the gate insulating film.

While the metal-containing layers flocculate in the form of dots through the heat supplied in the CVD step for forming the amorphous silicon layer after formation of the metal-containing layers by CVD, the heat treatment step for electrically activating the impurity and the remaining steps in the aforementioned embodiment, the present invention is not restricted to this but the metal-containing layers may alternatively be provided in the form of dots by controlling formation conditions in the CVD step for forming the metal-containing layers. Further alternatively, the metal-containing layers may be provided in the form of dots by subsequently performing heat treatment after forming the metal-containing layers by CVD.

While the metal-containing layers contain TaN in the aforementioned embodiment, the present invention is not restricted to this but the metal-containing layers may alternatively contain a material other than TaN. For example, the metal-containing layers may contain a metal silicide such as TiSi or TaSi, a simple metal or a metal nitride such as TiN.

While the gate insulating film is formed by the SiO₂ film in the aforementioned embodiment, the present invention is not restricted to this but the gate insulating film may alternatively be formed by a film other than the SiO₂ film. For example, an HfO_{X} film, a ZrO₂ film, an HfAlO film, an SiN film, an SiON film, an HfSiO film or an HfNO film may be employed as the film other than the SiO₂ film.

While the silicon substrate is employed in the aforementioned embodiment, the present invention is not restricted to this but a semiconductor substrate other than the silicon substrate may alternatively be employed. For example, an SOI (silicon on insulator) substrate having a silicon layer formed on an insulated substrate may be employed.

While the metal-containing layer containing TaN is employed as the lower metal-containing layer (first metal-containing layer) arranged on the interface between the gate electrode and the gate insulating film in the aforementioned embodiment, the present invention is not restricted to this but a metal-containing layer at least containing metal silicide grains having a metal concentration of at least about 50% may alternatively be employed as the lower metal-containing layer (first metal-containing layer) arranged on the interface between the gate electrode and the gate insulating film. According to this structure, the gate electrode can be prevented from Fermi-level pinning on the interface between the same and the gate insulating film when the gate insulating film is formed by a high-K film, whereby the threshold voltage of the MOS transistor can be easily controlled. Due to the metal silicide grains forming the metal-containing layers included in the gate electrode, further, the impurity can be efficiently diffused through grain boundaries of the materials (silicon-rich silicide, silicon grains, granular silicide and granular silicon) constituting the gate electrode when the gate electrode is doped by ion implantation of the impurity in the step of fabricating the MOS transistor. Therefore, the impurity concentration of the gate electrode can be easily controlled.

While the metal-containing layer containing TaN is employed as the upper metal-containing layer (second metal-containing layer) in the aforementioned embodiment, the present invention is not restricted to this but a metal-containing layer at least containing metal silicide grains having a metal concentration of at least about 50% may alternatively be employed as the upper metal-containing layer (second metal-containing layer). According to this structure, the impurity can be efficiently diffused through grain boundaries of the materials (silicon-rich silicide, silicon grains, granular silicide and granular silicon) constituting the gate electrode when the gate electrode is doped by ion implantation of the impurity in the step of fabricating the MOS transistor. Therefore, the impurity concentration of the gate electrode can be easily controlled.

What is claimed is:

1. A semiconductor device comprising:
a pair of source/drain regions formed on the main surface of a semiconductor region to hold a channel region therebetween; and
a gate electrode formed on said channel region through a gate insulating film, wherein
said gate electrode includes a first metal-containing layer, a second metal-containing layer formed on said first metal-containing layer and an intermediate layer formed between said first metal-containing layer and said second metal-containing layer.

2. The semiconductor device according to claim 1, wherein
said first metal-containing layer is so formed as to partially cover the surface of said gate insulating film.

3. The semiconductor device according to claim 2, wherein
said first metal-containing layer is provided in the form of dots to partially cover the surface of said gate insulating film.

4. The semiconductor device according to claim 2, wherein
said second metal-containing layer is so formed as to partially cover the surface of said intermediate layer, and
a region formed with said first metal-containing layer and a region formed with said second metal-containing layer deviate from each other in a direction parallel to the surface of said gate insulating film in plan view.

5. The semiconductor device according to claim 4, wherein
said second metal-containing layer is provided in the form of dots to partially cover the surface of said intermediate layer.

6. The semiconductor device according to claim 1, wherein
said intermediate layer includes a first semiconductor layer.

7. The semiconductor device according to claim 1, wherein
said first metal-containing layer and said second metal-containing layer are provided on the surfaces of said gate insulating film and said intermediate layer to disperse substantially over the whole areas thereof respectively.

8. The semiconductor device according to claim 1, wherein
said gate electrode further includes a second semiconductor layer formed on said second metal-containing layer, and
said first metal-containing layer and said second metal-containing layer are arranged in the vicinity of the interface between said gate electrode and said gate insulating film.

9. The semiconductor device according to claim 8, wherein
said second semiconductor layer includes a third semiconductor layer formed on said intermediate layer to come into contact with said second metal-containing layer and cover said second metal-containing layer and a fourth semiconductor layer formed on said third semiconductor layer.

10. The semiconductor device according to claim 9, wherein
the thickness of said fourth semiconductor layer is larger than the thickness of said third semiconductor layer.

11. The semiconductor device according to claim 9, wherein
said second metal-containing layer is arranged in the vicinity of the interface between said third semiconductor layer and said intermediate layer.

12. The semiconductor device according to claim 1, wherein
said first metal-containing layer and said second metal-containing layer are made of TaN.

13. A method of fabricating a semiconductor device, comprising steps of:
forming a gate electrode by successively forming a first metal-containing layer, an intermediate layer and a second metal-containing layer on the main surface of a semiconductor region through a gate insulating film; and
ion-implanting an impurity from above said gate electrode.

14. The method of fabricating a semiconductor device according to claim 13, wherein
said step of forming said gate electrode includes a step of forming said first metal-containing layer to partially cover the surface of said gate insulating film.

15. The method of fabricating a semiconductor device according to claim 14, wherein
said step of forming said first metal-containing layer includes a step of flocculating a first metal-containing film formed on said gate insulating film by heat treatment.

16. The method of fabricating a semiconductor device according to claim 14, wherein
said step of forming said gate electrode includes a step of forming said second metal-containing layer to partially cover the surface of said intermediate layer.

17. The method of fabricating a semiconductor device according to claim 16, wherein
said step of forming said second metal-containing layer includes a step of flocculating a second metal-containing film formed on said intermediate layer by heat treatment.

18. The method of fabricating a semiconductor device according to claim 16, wherein
said step of forming said gate electrode includes a step of forming said first metal-containing layer and said second metal-containing layer so that a region formed with said first metal-containing layer and a region formed with said second metal-containing layer deviate from each other in a direction parallel to the surface of said gate insulating film in plan view.

19. The method of fabricating a semiconductor device according to claim 13, wherein
said step of forming said gate electrode includes steps of forming said first metal-containing layer on said gate insulating film and forming said intermediate layer to cover said first metal-containing layer formed on said gate insulating film.

20. The method of fabricating a semiconductor device according to claim 19, wherein
said step of forming said gate electrode further includes steps of forming said second metal-containing layer on said intermediate layer and forming a semiconductor layer to cover said second metal-containing layer formed on said intermediate layer.
